(19) United States
(12) Patent Application Publication
(10) Pub. No.: US 2026/0072091 A1
(43) Pub. Date: Mar. 12, 2026

(54) METHOD OF MANUFACTURING POWER STORAGE DEVICE

(71) Applicant: TOYOTA JIDOSHA KABUSHIKI KAISHA, Toyota-shi (JP)

(72) Inventors: Shinya TAKESHITA, Toyota-shi (JP); Mitsuru TATEISHI, Toyota-shi (JP); Chihiro MATSUDA, Toyohashi-shi (JP)

(73) Assignee: TOYOTA JIDOSHA KABUSHIKI KAISHA, Toyota-shi (JP)

(21) Appl. No.: 19/271,055

(22) Filed: Jul. 16, 2025

(30) Foreign Application Priority Data
Sep. 9, 2024 (JP) 2024-154662

(51) Int. Cl. G01R 31/385; G01R 31/389; H01M 4/02; H01M 10/052; H01M 50/204; H01M 50/51

(52) U.S. Cl. CPC G01R 31/3865; G01R 31/389; H01M 10/052; H01M 50/204; H01M 50/51; H01M 2004/029

(57) ABSTRACT

A method of manufacturing a power storage device including plural power storage cells includes a wire forming process of forming a wire of the power storage device such that adjacent power storage cells in the power storage device are connected to a common wire, and a resistance measuring process of measuring an electrical resistance of at least a part of the formed wire. In the resistance measurement process, the voltage of the open circuit including the second power storage cell and the common wire portion is measured while a current is supplied to the closed circuit including the first power storage cell and the common wire portion with respect to the common wire portion of the first power storage cell and the second power storage cell adjacent to each other in the power storage device, and the electrical resistance of the common wire portion is acquired using the measured voltage.

### CROSS-REFERENCE TO RELATED APPLICATION

This application claims priority to Japanese Patent Application No. 2024-154662 filed on Sep. 9, 2024. The disclosure of the above-identified application, including the specification, drawings, and claims, is incorporated by reference herein in its entirety.

### BACKGROUND

### 1. Technical Field

The present disclosure relates to a method of manufacturing a power storage device.

### 2. Description of Related Art

Japanese Unexamined Patent Application Publication No. 2014-180109 (JP 2014-180109 A) discloses a technique of calculating a resistance value of a charging path based on a voltage of a secondary battery (a voltage value across the secondary battery), a charging current, and a power supply voltage (an output voltage of a power supply) during charging of the secondary battery.

### SUMMARY

In a power storage device including a plurality of power storage cells, each of the power storage cells functions as a secondary battery, for example. In such a power storage device, the voltage of the power storage cell tends to increase as the storage amount of the power storage cell increases. Therefore, the voltage of the power storage cell may fluctuate during charging of the power storage cell. When the output voltage of a power supply connected to the power storage cell is constant, the charging current also changes when the voltage of the power storage cell changes. In this manner, the voltage and the charging current of the power storage cell tend to be unstable during charging of the power storage cell. Therefore, in the technique described in JP 2014-180109 A, it is difficult to accurately measure the electrical resistance of a wire (a charging path, for example) connected to a power storage cell.

The present disclosure has been made in order to address the above issue, and has an object to measure the electrical resistance of a wire connected to a power storage cell in a power storage device with high accuracy.

An aspect of the present disclosure provides a method of manufacturing a power storage device including a plurality of power storage cells. The method includes:
forming wires of the power storage device such that power storage cells adjacent to each other in the power storage device are connected to a common wire; and
measuring an electrical resistance of at least a part of the formed wires. The measuring of the electrical resistance includes measuring, for a common wire portion between a first power storage cell and a second power storage cell adjacent to each other in the power storage device, a voltage of an open circuit including the second power storage cell and the common wire portion while supplying a current to a closed circuit including the first power storage cell and the common wire portion, and acquiring an electrical resistance of the common wire portion using the measured voltage.

According to the present disclosure, it is possible to measure the electrical resistance of a wire connected to a power storage cell in a power storage device with high accuracy.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a flowchart illustrating a method of manufacturing a power storage device according to the present embodiment;

FIG. 2 is a cross-sectional view illustrating a configuration of a laminate included in an inspection target;

FIG. 3 is a diagram for describing an inspection according to the present embodiment;

FIG. 4 is a diagram for describing a resistivity measuring process according to the present embodiment; and

FIG. 5 is a diagram illustrating a modification of the resistance measurement process.

### DETAILED DESCRIPTION OF EMBODIMENTS

Embodiments of the present disclosure will be described in detail with reference to the drawings. In the drawings, the same or corresponding parts are denoted by the same reference numerals, and the description thereof will not be repeated. In the figures used below, the X-axis, the Y-axis, and the Z-axis represent three axes orthogonal to each other. Hereinafter, “+” is indicated in the direction indicated by the arrows of the X axis, the Y axis, and the Z axis, and “−” is indicated in the opposite direction.

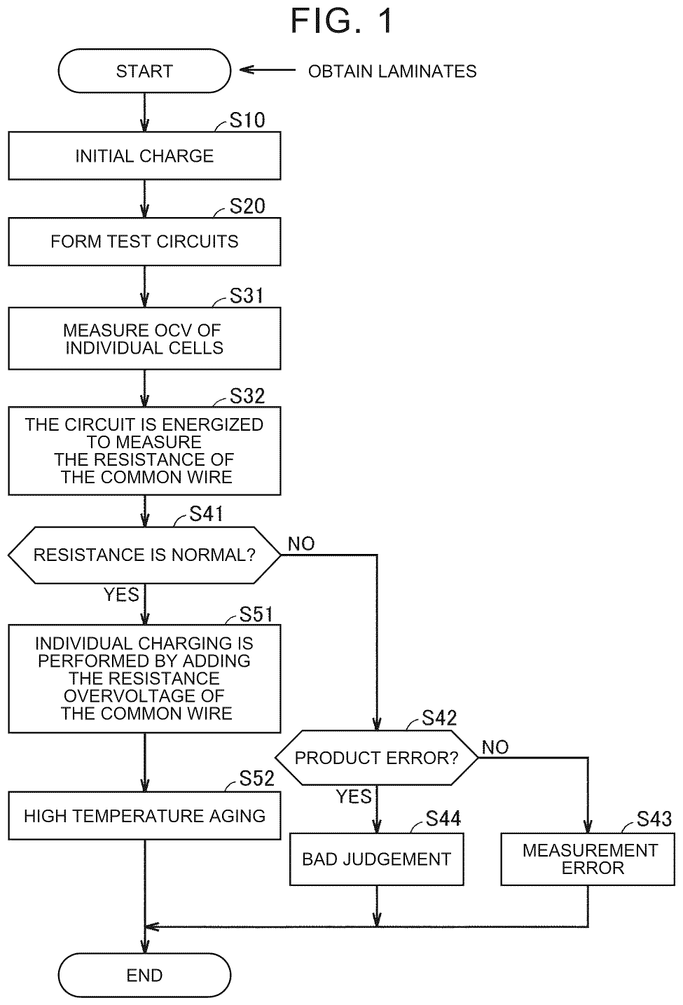

FIG. 1 is a flowchart illustrating a processing procedure of an inspection according to this embodiment. In the method for manufacturing a power storage device according to this embodiment, first, an inspection target is prepared. Then, an inspection is performed on the inspection target by the processing flow illustrated in FIG. 1.

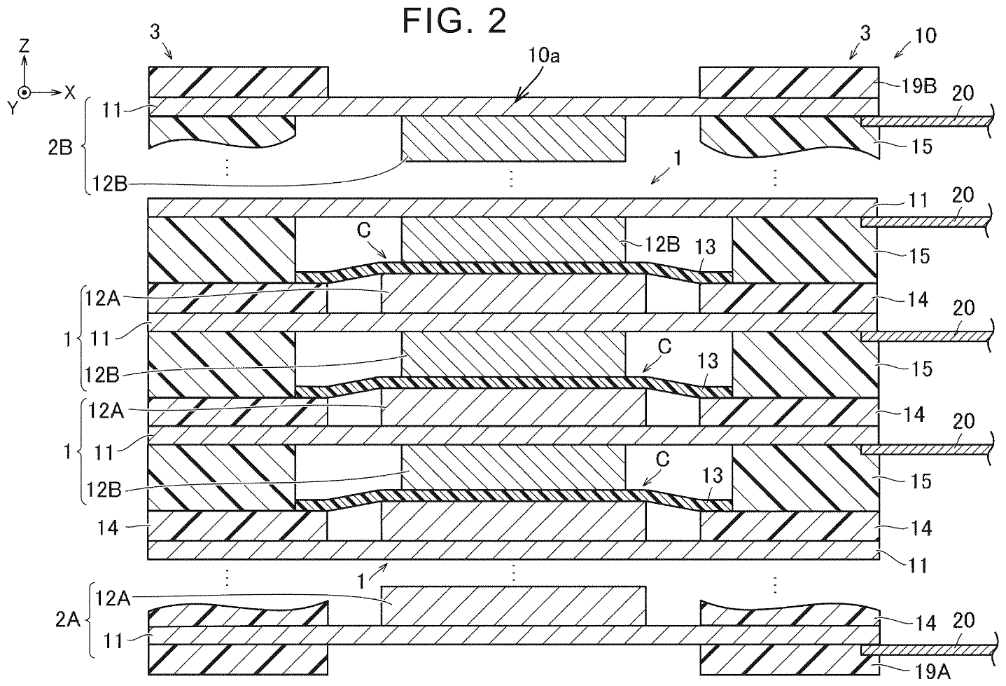

The inspection target according to this embodiment includes the stacked body 10 shown in FIG. 2. FIG. 2 is a cross-sectional view illustrating a configuration of a laminate included in an inspection target. Referring to FIG. 2, the stacked body 10 includes a power storage unit 10a and a sealing portion 3 that seals the power storage unit 10a. The Z direction corresponds to the stacking direction. The power storage unit 10a includes a plurality of cells C (unit-cells) arranged in the Z-direction. Each of the plurality of cells C includes a negative electrode active material layer 12A, a positive electrode active material layer 12B, and separators 13.

Each of the plurality of cells C is configured to be capable of storing electricity. Each of the plurality of cells C functions as a secondary battery. Each of the plurality of cells C corresponds to an example of a “power storage cell” according to the present disclosure. In this embodiment, the power storage unit 10a includes N cells C. In this embodiment, N is not less than 10 and less than 50. However, the total number (N) of cells C may be 3 or more and less than 10, or may be 50 or more. The sealing portion 3 is formed so as to surround the power storage unit 10a. The space surrounded by the sealing portion 3 is filled with an electrolytic solution. The electrolyte is impregnated into the separator 13.

The stacked body 10 includes a plurality of electrodes (one negative terminal electrode 2A, a plurality of bipolar electrodes 1, and one positive terminal electrode 2B) stacked along the Z-direction. A separator 13 is disposed between the electrodes. The bipolar electrode 1 includes a current collector 11, a negative electrode active material layer 12A provided on the +Z side surface of the current collector 11, and a positive electrode active material layer 12B provided on −Z side surface of the current collector 11. The negative electrode termination electrode 2A has a configuration in which the positive electrode active material layers 12B are removed from the bipolar electrode 1. On −Z surface of the current collector 11 constituting the negative electrode termination electrode 2A, an insulating layer 19A covering the peripheral edge portion of the current collector 11 is formed. The positive electrode termination electrode 2B has a configuration in which the negative electrode active material layers 12A are removed from the bipolar electrode 1. On the +Z-side surface of the current collector 11 constituting the positive electrode termination electrode 2B, an insulating layer 19B covering the peripheral edge portion of the current collector 11 is formed.

In this embodiment, a metal foil (for example, aluminum foil) is used as the current collector 11 of each electrode. A surface treatment (for example, plating treatment) may be applied to one or both surfaces of the metal foil. A voltage detection terminal 20 is connected to the current collector 11 of each electrode. In this embodiment, the voltage detection terminal 20 comprises stainless steel. Stainless steel is excellent in corrosion resistance, heat resistance, and workability. However, the material of the voltage detection terminal 20 can be changed as appropriate.

The negative electrode active material layer 12A includes a negative electrode active material. The positive electrode active material layer 12B includes a positive electrode active material. In one embodiment, the positive electrode active material is olivine-type lithium iron phosphate (LiFePO₄), the negative electrode active material is a carbon-based material, and the electrolyte is a non-aqueous electrolyte. However, another example of the negative electrode active material includes silicon and tin. The electrolytic solution may be an aqueous electrolytic solution. Alternatively, a gel-like or solid-like electrolyte may be used instead of the electrolyte.

In the stacked body 10, a cell C is formed between the plurality of stacked current collectors 11. Specifically, a cell C is formed between a current collector 11 (first current collector) and a current collector 11 (second current collector) adjacent to the first current collector. Furthermore, a cell C is also formed between the second current collector and the current collector 11 (third current collector) adjacent to the second current collector. In this way, the current collector 11 and the cell C are alternately arranged in the stacking direction of the stacked body 10. The sealing portion 3 includes sealing layers 14 and 15 disposed around each of the plurality of cells C included in the stacked body 10, and the insulating layer 19A, 19B described above. Any sealing material can be used as the material of the sealing portion 3.

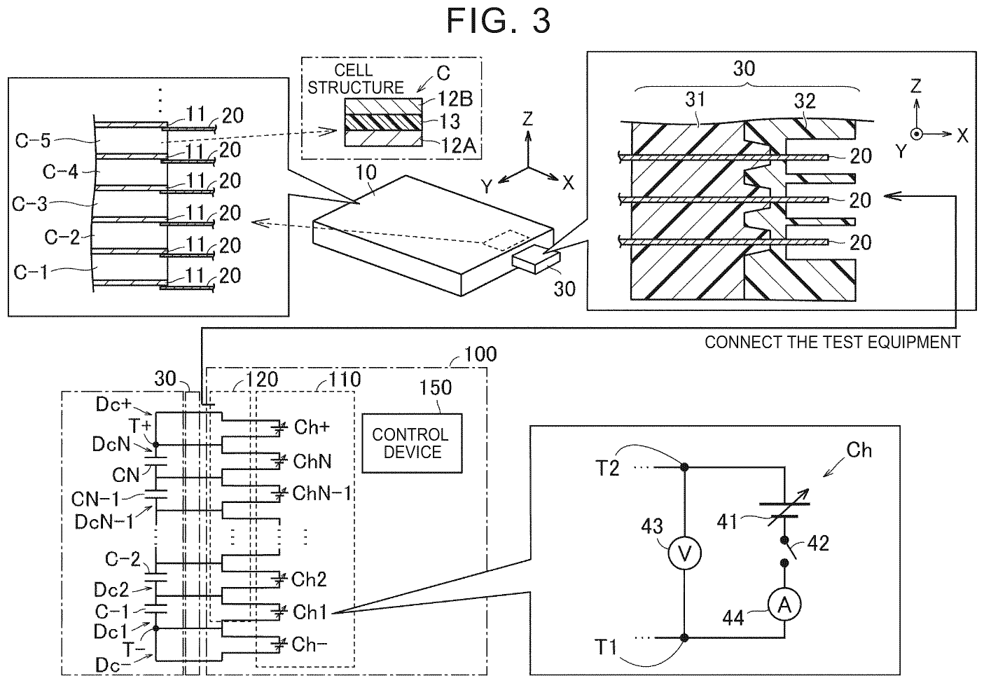

The stacked body 10 functions as a bipolar secondary battery. In the stacked body 10, a plurality of cells C are electrically connected in series. Each of the plurality of cells C included in the stacked body 10 functions as, for example, a LFP cell (a lithium-ion secondary battery including lithium iron phosphate as a positive electrode active material). In the following description, the first, second,. (N-1)-th, and N-th cells C from the end of the stacked body 10 on the negative electrode side (−Z side) may be represented as cell C-1, cell C-2, . . . cell CN−1, and cell CN, respectively (see FIG. 3 described later). In the stacked body 10, a plurality of cells are stacked in the Z direction. Adjacent cells have a common electrode. Specifically, the current collector 11 and the voltage detection terminal 20 located between adjacent cells function as a common electrode. This common electrode functions as a common wire to be described later (see FIG. 3).

For example, the manufacturing system forms the stacked body 10 (FIG. 2) to which the voltage detection terminal 20 described above is connected through various processes. Various processes include processes such as coating, pressing, seal welding, separator welding, cutting, terminal (voltage detection terminal) welding, end face welding, injection molding, liquid injection, and temporary sealing. Although not shown in FIG. 2, the voltage detection terminal 20 is further provided with a connector 30 (see FIG. 3), which will be described later. Further, the stacked body 10 may be restrained by a restraining jig. The stacked body 10 may be pressed by being sandwiched between a pair of end plates (restraining plates).

The manufacturing system according to this embodiment includes a system for preparing the stacked body 10 and an inspection system for charging, aging, and inspecting the stacked body 10. The system for preparing the stacked body 10 is a system including a device corresponding to each step for forming the stacked body 10. Testing includes circuit resistance measurement and self-discharge testing. However, it is not essential that the manufacturing (including inspection) of the power storage device is automatically performed (that is, all processing related to manufacturing is performed by the device), and a person (worker) may perform some processing. The structure of the stacked body 10 is not limited to the structure shown in FIG. 2, and can be changed as appropriate.

Referring again to FIG. 1, once the stacked body 10 obtained as described above (e.g., the stacked body 10 in a constrained state) is passed to the inspection system, the inspection system executes the process flow shown in FIG. 1 for the stacked body 10. “S” in the flowchart means a step.

In S10, the test-system performs the initial charge of the stacked body 10. The initial charging is the first charging of the formed stacked body 10. For example, the inspection system applies a voltage between the positive electrode terminal and the negative electrode terminal of the stacked body 10 (for example, the current collector 11 located at both ends in the Z direction shown in FIG. 2). As a result, all the cells C connected in series are charged. SOC (State Of Charge) of the at least one cell included in the stacked body 10 may be equal to or greater than the target SOC value. SOC indicates the amount of stored electricity, and represents, for example, the ratio of the present amount of stored electricity to the amount of stored electricity in a fully charged state from 0 % to 100%. The target SOC can be set arbitrarily. The target SOC may be 50% or more and 100% or less, for example, about 90%. Note that the condition for ending the initial charging may be set not by SOC but by the charging period.

Subsequently, the inspection system forms the inspection circuitry by connecting the stacked body 10 to the power supply of the inspection system at S20. Hereinafter, S20 and subsequent processes will be described with further reference to FIG. 3. FIG. 3 is a diagram for explaining inspection of the stacked body 10. As shown in FIG. 3, a connector 30 is provided for a plurality of voltage detection terminals 20 connected to the stacked body 10. The voltage detection terminal 20 is welded to, for example, an end portion of the current collector 11 on the +X side. Examples of welding methods include ultrasonic welding or laser welding. The connector 30 includes a resin portion 31 and a housing 32. For example, in a state in which the housing 32 for aligning the voltage detection terminals 20 is attached to the distal end of the voltage detection terminals 20, the resin portion 31 connecting the end face on the +X side of the stacked body 10 and the housing 32 is formed by injection molding. As a result, the connector 30 in a state of being joined to the stacked body 10 is formed. The plurality of voltage detection terminals 20 are configured to be connectable to an external power source (for example, the DC power supply 41). Each of the plurality of voltage detection terminals 20 functions as a pin of the connector 30. The connector 30 is a male connector and is configured to be attachable to a female connector.

The inspection system according to this embodiment includes an inspection device 100. The inspection device 100 includes a power supply unit 110, a connection unit 120, and a control device 150. The control device 150 includes a processor and a storage device. In this embodiment, the inspection is executed by the processor executing a program stored in the storage device. However, each process related to the inspection may be executed only by hardware (electronic circuit) without using software.

The power supply unit 110 includes a plurality of test channels (hereinafter, referred to as “Ch”). Ch includes a DC power supply 41, a switch 42, a voltmeter 43, an ammeter 44, and a terminal T1, T2. The output voltage of the DC power supply 41 is variable. The ammeter 44 is connected in series to the DC power supply 41, and the voltmeter 43 is connected in parallel. The switch 42 switches between circuit interruption and connection by an opening/closing operation. Each of the DC power supply 41 and the switch 42 is controlled by the control device 150. The voltmeter 43 detects the voltage between the terminals T1, T2. The ammeter 44 detects the current flowing through the circuitry connected to Ch.

The connection unit 120 functions as a female connector (for example, a combitack) that can be attached to the connector 30. In S20 of FIG. 1, the inspection device 100 connects the connector 30 to the connection unit 120. The inspection device 100 may include a robot to which a connector is connected.

A corresponding terminal (for example, a female terminal) of the connection portion 120 is connected to each terminal (for example, a male terminal) of the connector 30, so that each cell included in the stacked body 10 is connected to the power supply unit 110 of the inspection device 100. As a result, a test circuit is formed for each cell. The inspection circuit of the adjacent cells C (power storage cells) has a common wire portion. The test circuits are circuits including a cell C, a channel (Ch), and a common wire. In either test circuit, the test circuit is closed when the switch 42 is closed, and the test circuit is open when the switch 42 is open. Hereinafter, the test circuits provided for the cell C-1, the cell C-2, . . . the cell CN-1, and the cell CN may be represented as test circuits Dc1, test circuits Dc2,. test circuits DcN-1, and test circuits DcN, respectively.

A total positive terminal T+ is provided at an end of the entire stacked body 10 on the positive electrode side. A total negative terminal T− is provided at an end of the stacked body 10 on the negative electrode side. Further, wires (more specifically, wires connectable to Ch) of the terminal circuits Dc and Dc− are formed inside or outside the stacked body 10. By connecting the connection unit 120 to the connector 30, Ch of the power supply unit 110 is connected to the total positive terminal T+, and another Ch of the power supply unit 110 is also connected to the total negative terminal T−. As a result, a terminal circuit Dc+ that does not include a power storage cell and a terminal circuit Dc− that does not include a power storage cell are formed. The terminal circuit Dc+ is located next to the cell CN opposite the cell CN-1. The terminal circuit Dc− is located next to the cell C-1 opposite the cell C-2. Hereinafter, the channels (Ch) provided for the total negative terminal T-, the cell C-1, the cell C-2, . . . the cell CN-1, the cell CN, and the total positive terminal T+ may be represented by Ch−, Ch1, Ch2,. ChN-1, ChN, Ch+, respectively. In the following description, the voltage value detected by Ch−, Ch1, Ch2, . . . ChN-1, ChN, Ch+ (the value detected by the voltmeter 43) may be expressed as Vx, V₁, V₂, . . . V_{N-1}, V_{N}, and Vy, respectively.

In the following S31, the inspection device 100 sets the switches 42 of the respective Ch included in the power supply unit 110 to the open state (cut-off state), and measures OCV (Open Circuit Voltage) of the respective cells included in the stacked body 10 in the stacked body 10 in the non-energized state. Hereinafter, OCV of the cell C-1, the cell C-2, . . . the cell CN-1, and the cell CN may be expressed as OCV₁, OCV₂, . . . OCV_{N-1}, OCV_{N}, respectively. In this embodiment, S31 process corresponds to an exemplary “cell-voltage measure” according to the present disclosure.

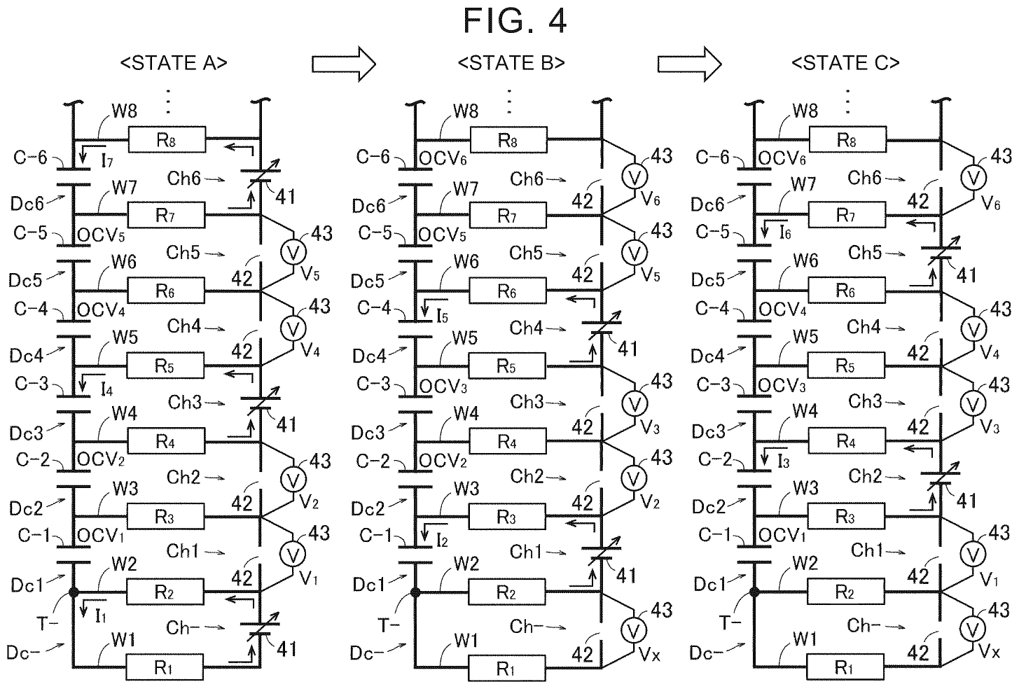

After measuring OCV, the process proceeds to S32. Hereinafter, S32 process will be described further with reference to FIG. 4. FIG. 4 is a diagram for explaining resistance measurement processing of each test circuit. In FIG. 4, the wire W1 corresponds to an independent wire portion of the terminal circuit Dc−, that is, a portion of the terminal circuit Dc− excluding the wire W2. The wire W2 corresponds to a common portion (first common wire portion) between the terminal circuit Dc− and the test circuit Dc1 (wire of the cell C-1). The wire W3 corresponds to a common wire portion (second common wire portion) of the cell C-1 and the cell C-2. The wire W4 corresponds to a common wire portion (third common wire portion) of the cell C-2 and the cell C-3. The wire W5 corresponds to a common wire portion (fourth common wire portion) of the cell C-3 and the cell C-4. The wire W6 corresponds to a common wire portion (fifth common wire portion) of the cell C-4 and the cell C-5. The wire W7 corresponds to a common wire portion (sixth common wire portion) of the cell C-5 and the cell C-6. The wire W8 corresponds to a common wire portion (seventh common wire portion) of the cell C-6 and the cell C-7.

Although not shown in FIG. 4, the terminal circuit Dc+also has an independent wire part (hereinafter, referred to as “wire WN+3”) in a manner similar to the terminal circuit Dc−. The terminal circuit Dc+and the test circuit DcN (the wire of the cell CN) have a common wire part (hereinafter, referred to as “wire WN+2”). The cell CN and the cell CN-1 also have a common wire part (hereinafter, referred to as “wire WN+1”). In the stacked body 10, each pair formed by adjacent cells has a common wire portion. Hereinafter, the wire W1, the wire W2,. the wire WN+1, the wire WN+2, and the resistance value (electrical resistance) of the wire WN+3 will be referred to as R₁, R₂, . . . R_{N+1}, R_{N+2}, and R_{N+3}, respectively. Each of the R₁ and the R_{N+3} is smaller than the other resistance values (wire resistance of the cell). Each of the R1 and R_{N+3} may be 1/10 or less of each of the R_{N+2} from the R₂, or may be about 0.01 Ω.

The resistance measurement process according to this embodiment includes the first resistance measurement, the second resistance measurement, and the third resistance measurement described below. In S32 of FIG. 1, the inspection device 100 performs the first to third resistive measurements. The inspection device 100 may acquire the wire resistance on the basis of the formula “wire resistance=voltage change amount/energization current of the adjacent cell during energization”.

In the first resistance measurement, the inspection device 100 sets the stacked body 10 to the state A shown in FIG. 4. Specifically, the control device 150 controls the switches 42 of the respective Ch so that the terminal circuit Dc− and the “3×M” th test circuit from the negative-side end of the stacked body 10 are closed circuits and the other test circuits are open circuits. M is an integer greater than or equal to 1 and less than or equal to “N/3 (N of 3)”. Then, the inspection device 100 measures the resistance values (R₂, R₄, R₅, R₇, R₈,.) of the stacked body 10 in the state A from the wire W1 to WN+3, excluding the “3×M” th wire and the wire W1, WN+3 from the negative electrode-side end of the stacked body 10, as described below.

With a predetermined current (hereinafter, referred to as “I₁”) flowing through the terminal circuit Dc− including the wire W2, the test circuit Dc1 (open circuit including the cell C-1 and the wire W2) is measured. Then, using the measured voltage (V₁) and the open circuit voltage of the cell C-1 (S31 measured OCV₁), the electrical resistance (R₂) of the wire W2 is calculated. The control device 150 may calculate R₂ based on the formula “R₂×I₁=OCV₁- V₁”.

With a predetermined current (hereinafter, referred to as “I₄”) flowing through the inspection circuit Dc3 including the wire W4, the voltage of the inspection circuit Dc2 (the open circuit including the cell C-2 and the wire W4) is measured. Then, using the measured voltage (V₂) and the open circuit voltage of the cell C-2 (S31 measured OCV₂), the electrical resistance (R₄) of the wire W4 is calculated. The control device 150 may calculate R4 based on the equation “R₄×I₄=OCV₂-V₂”.

With the above-described current (I₄) flowing through the inspection circuit Dc3 including the wire W5, the voltage of the inspection circuit Dc4 (the open circuit including the cell C-4 and the wire W5) is measured. Then, the measured voltage (V₄) and the open circuit voltage of the cell C-4 (S31 measured OCV₄) are used to calculate the electrical resistance (R₅) of the wire W5. The control device 150 may calculate R₅ based on the formula “R₅×I₄=OCV₄-V₄”.

With a predetermined current (hereinafter, referred to as “I₇”) flowing through the inspection circuit Dc6 including the wire W7, the voltage of the inspection circuit Dc5 (the open circuit including the cell C-5 and the wire W7) is measured. Then, the measured voltage (V₅) and the open circuit voltage of the cell C-5 (S31 measured OCV₅) are used to calculate the electrical resistance (R₇) of the wire W7. The control device 150 may calculate R₇ based on the equation “R₇×I₇=OCV₅-V₅”.

Resistance values (R₈ or later) of other wires to be measured can also be obtained in a manner similar to that described above.

When the first resistance measurement is completed, the inspection device 100 performs the second resistance measurement after updating OCV_{N} from OCV₁ by measuring OCV of the cells again in the same manner as in S31. In the second resistance measurement, the inspection device 100 sets the stacked body 10 to the state B shown in FIG. 4. Specifically, the control device 150 controls the switches 42 of the respective Ch such that the terminal circuit Dc+ and the “3×M-2” test circuit from the negative end of the stacked body 10 are closed circuits and the other test circuits are open circuits. Then, the inspection device 100 measures the resistance value (R₃, R₆, R₉, . . .) of the “3×M” th wire from the negative electrode-side end of the stacked body 10 among WN+2 from the wire W2, as described below, for the stacked body 10 in the state B.

With a predetermined current (hereinafter, referred to as “I₂”) flowing through the inspection circuit Dc1 including the wire W3, the voltage of the inspection circuit Dc2 (the open circuit including the cell C-2 and the wire W3) is measured. Then, the measured voltage (V₂) and the open circuit voltage of the cell C-2 (OCV₂) are used to calculate the electrical resistance (R₃) of the wire W3. The control device 150 may calculate R₃ based on the equation “R₃×I₂=OCV₂-V₂”.

With a predetermined current (hereinafter, referred to as “I₅”) flowing through the inspection circuit Dc4 including the wire W6, the voltage of the inspection circuit Dc5 (the open circuit including the cell C-5 and the wire W6) is measured. Then, the measured voltage (V₅) and the open circuit voltage of the cell C-5 (OCV₅) are used to calculate the electrical resistance (R₆) of the wire W6. The control device 150 may calculate R₆ based on the equation “R₆×I₅=OCV₅-V₅”.

Resistance values (R₉ or later) of other wires to be measured can also be obtained in a manner similar to that described above.

Further, in the state B, the inspection device 100 performs the second measurement on the resistance value (R₂, R₅, R₈,.) of the “3×M-1” th wire from the negative electrode-side end of the stacked body 10 among WN+2 from the wire W2, as shown below.

With the above-described current (I₂) flowing through the test circuit Dc1 including the wire W2, the voltage of the terminal circuit Dc− including the wire W2 is measured, and the R₂ is calculated using the measured voltage (Vx) and the potential of the total negative terminal T− (hereinafter, referred to as “Vg”). The control device 150 may calculate R₂ based on the equation “R₂×I₂=Vg-Vx”. Vg is, for example, 0 V. Vx is negative.

With the above-described current (I₅) flowing through the inspection circuit Dc4 including the wire W5, the voltage of the inspection circuit Dc3 (the open circuit including the cell C-3 and the wire W5) is measured, and the R₅ is calculated using the measured voltage (V₃) and the open circuit voltage (OCV₃) of the cell C-3. The control device 150 may calculate R₅ based on the formula “R₅×I₅=OCV₃-V₃”.

Resistance values (R₈ or later) of other wires to be measured can also be obtained in a manner similar to that described above.

When the second resistance measurement is completed, the inspection device 100 performs the third resistance measurement after updating OCV_{N} from OCV₁ by measuring OCV of the cells again in the same manner as in S31. In the third resistance measurement, the inspection device 100 sets the stacked body 10 to the state C shown in FIG. 4. Specifically, the control device 150 controls the switches 42 of the respective Ch so that the “3×M-1” th test circuit from the negative-side end of the stacked body 10 becomes a closed circuit and the other test circuits and the respective terminal circuits become an open circuit. Then, the inspection device 100, in the state C, as shown below, among WN+2 from the wire W2, the resistance value of the “3×M” th wire from the end of the negative electrode side of the stacked body 10 (R₃, R₆, R₉, . . .) and the resistance value of the “3×M-2” th wire from the end of the negative electrode side of the stacked body 10 (R₄, R₇, R₁₀, . . .) perform the second measurement.

With a predetermined current (hereinafter, referred to as “I3”) flowing through the inspection circuit Dc2 including the wire W3, the voltage of the inspection circuit Dc1 (the open circuit including the cell C-1 and the wire W3) is measured. Then, the R₃ is calculated using the measured voltage (V₁) and the open circuit voltage of the cell C-1 (OCV₁). The control device 150 may calculate R₃ based on the formula “R3×I₃=OCV₁-V₁”.

With the above-described current (I₃) flowing through the inspection circuit Dc2 including the wire W4, the voltage of the inspection circuit Dc3 (the open circuit including the cell C-3 and the wire W4) is measured, and the R₄ is calculated using the measured voltage (V₃) and the open circuit voltage (OCV₃) of the cell C-3. The control device 150 may calculate R₄ based on the formula “R₄×I₃=OCV₃-V₃”.

With a predetermined current (hereinafter, referred to as “I₆”) flowing through the inspection circuit Dc5 including the wire W6, the voltage of the inspection circuit Dc4 (the open circuit including the cell C-4 and the wire W6) is measured. Then, the R₆ is calculated using the measured voltage (V₄) and the open circuit voltage of the cell C-4 (OCV₄). The control device 150 may calculate R₆ based on the formula “R₆×I₆=OCV₄-V₄”.

With the above-described current (I₆) flowing through the inspection circuit Dc5 including the wire W7, the voltage of the inspection circuit Dc6 (the open circuit including the cell C-6 and the wire W7) is measured, and the R₇ is calculated using the measured voltage (V₆) and the open circuit voltage (OCV₆) of the cell C-6. The control device 150 may calculate R₇ based on the formula “R₇×I₆=OCV₆-V₆”.

Resistance values (R₉ or later) of other wires to be measured can also be obtained in a manner similar to that described above.

By the process of the above S32, two readings are obtained for each of the R_{N+2} from the R₂. Each of the I₁ to the I₇ may be 1 A. In the following S41, the control device 150 determines whether or not all the resistances (R₂ to R_{N+2}) are normal.

Specifically, the control device 150 determines whether or not the difference (measurement error) between the first measurement value and the second measurement value is within a predetermined range (hereinafter, referred to as a “first range”) with respect to the respective resistance values (R₂ to R_{N+2}) measured by S32. The first range is set in advance as an allowable range of the measurement error. If the measured error exceeds the first range, S41 determines NO and the process proceeds to S42.

On the other hand, if the measurement error is within the first range, the control device 150 determines either the first measurement value or the second measurement value, or the average value of these measurements, as the final measurement value of each resistance value. Thereafter, the control device 150 determines whether or not all the resistance values (R₂ to R_{N+2}) are within a predetermined range (hereinafter, referred to as a “second range”). The second range is set in advance as a normal range of the resistance value.

If all the resistances are within the second range, S41 determines YES and the process proceeds to S51. On the other hand, if any of the resistances exceeds the second range, S41 determines NO, and the process proceeds to S42.

In S42, the control device 150 determines whether or not the resistance-value abnormality is an abnormality (product-abnormality) caused by the stacked body 10. If the measurement error exceeds the first range, it is determined that the measurement error is not a product abnormality (NO in S42), and the control device 150 determines that the resistance value abnormality is an abnormality caused by a measurement error (such as a contact failure) in a subsequent S43. When any of the final measured values of the R_{N+2} from the R₂ exceeds the second range, it is determined that S42 is YES, and the control device 150 determines that the stacked body 10 is a defective product in a subsequent S44. The control device 150 may notify and/or record the determination result. As a result, the inspection of the stacked body 10 is completed.

In S51, the test-system uses the resistivity measured by S32 (at least one of the R₂ to the R_{N+2}) to individually charge the cells included in the stacked body 10. The test circuitry (including Ch) formed for the respective cells may be used to perform the individual charge. The inspection system uses the measured resistance value to set the voltage at the time of individual charging. For example, the inspection system performs individual charging of each cell by adding the resistance overvoltage of the common wire.

In a subsequent S52, the test-system performs hot aging of the stacked body 10. The inspection system maintains the temperature of the stacked body 10 at a predetermined aging temperature until a predetermined aging time has elapsed. The high-temperature aging is aging at a temperature higher than the normal temperature. The aging temperature may be 50° C. or more and 85° C. or less. The aging time can be set arbitrarily. The aging time may be 5 hours or more and 20 hours or less. After the aging time has elapsed, the inspection system may cool the stacked body 10 to room temperature to perform a self-discharge inspection of the stacked body 10.

As described above, the method of manufacturing the power storage device according to this embodiment includes the respective processes illustrated in FIG. 1. This method includes a wire forming process (see FIGS. 2 and 3) of forming a wire of the power storage device such that adjacent power storage cells in the power storage device are connected to a common wire (for example, the current collector 11 and the voltage detection terminal 20). Further, a resistance measuring process (S31, S32) for measuring an electrical resistance of at least a part of the formed wire is included. In S32, a current is supplied to the first power storage cell and the closed circuit including the common wire portion with respect to the common wire portion of the first power storage cell and the second power storage cell adjacent to each other in the power storage device. In the meantime, the voltage of the open circuit including the second power storage cell and the common wire portion is measured, and the electrical resistance of the common wire portion is obtained by using the measured voltage.

In the open circuit, the charge and discharge of the second power storage cell are not performed, and thus the amount of power storage of the second power storage cell (and thus the cell voltage) is stabilized. According to the above method, by determining the electrical resistance by using the voltage of the open circuit, the electrical resistance of the common wire portion of the first power storage cell and the second power storage cell adjacent to each other can be obtained with high accuracy. In this embodiment, the cell C-1, the cell C-2, the cell C-3, the cell C-4, the cell C-5, and the cell C-6 correspond to the first power storage cell, the second power storage cell, the third power storage cell, the fourth power storage cell, the fifth power storage cell, and the sixth power storage cell, respectively.

The stacked body 10 determined to be a non-defective product by the above inspection can function as a power storage device (bipolar secondary battery) alone. However, the power storage device may be manufactured by combining a plurality of modules using the stacked body 10 as one module. The manufactured power storage device may be mounted on a moving body. Exemplary mobile objects include automobiles (such as battery electric vehicle, hybrid electric vehicle), vehicles other than automobiles, and mobile machines (such as agricultural machinery and building machinery). However, the use of the power storage device is arbitrary, and a stationary battery may be manufactured by the above-described method.

The processing flow illustrated in FIG. 1 can be changed as appropriate. For example, the order of processing may be changed or the contents of any processing may be changed according to the purpose.

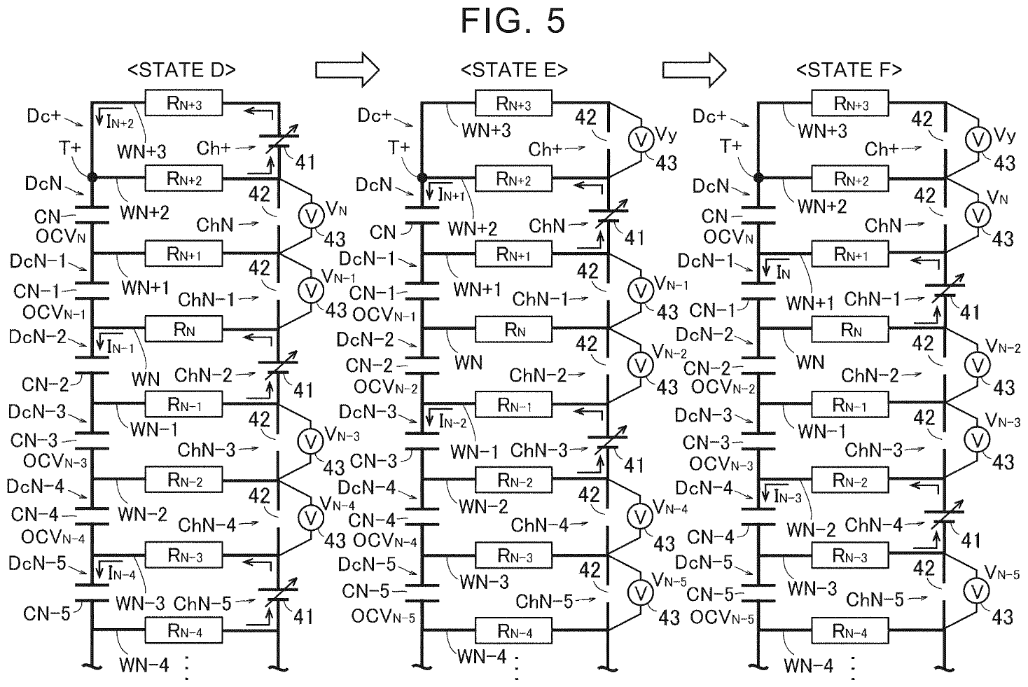

In the above-described embodiment, in S32 of FIG. 1, the first resistance measurement, the second resistance measurement, and the third resistance measurement are performed in the state A, the state B, and the state C shown in FIG. 4, respectively. However, the present disclosure is not limited thereto, and the first resistance measurement, the second resistance measurement, and the third resistance measurement may be performed in the state D, the state E, and the state F illustrated in FIG. 5, respectively. FIG. 5 is a diagram illustrating a modification of the resistance measurement process.

In the first resistance measurement according to the modification, the inspection device 100 sets the stacked body 10 to the state D shown in FIG. 5. Specifically, the control device 150 controls the switches 42 of the respective Ch so that the terminal circuit Dc+ and the “3×M” th test circuit from the positive-side end of the stacked body 10 are closed circuits and the other test circuits are open circuits. M is an integer greater than or equal to 1 and less than or equal to “N/3 (N of 3)”. Then, the inspection device 100, in the state D, for example, obtains R_{N+2} based on the formula “R_{N+2}×I_{N+2}=OCV_{N}-V_{N}”. Then, R_{N} is obtained based on the expression “R_{N}×I_{N-1}=OCV_{N-1}-V_{N-1}”. Then, R_{N-1} is obtained based on the expression “R_{N-1}×I_{N-1}=OCV_{N-3}-V_{N-3}”. Then, R_{N-3} is obtained based on the expression “R_{N-3}×I_{N-4}=OCV_{N-4}-V_{N-4}”. In addition, I_{N+2}, I_{N-1}, and I_{N-4} indicate currents flowing through the terminal circuit Dc+, the test circuit DcN-2, and the test circuit DcN-5, respectively.

After completion of the first resistance measurement, the inspection device 100 updates OCV_{N} from OCV₁, and then performs the second resistance measurement in the state E. Specifically, the control device 150 controls the switches 42 of the respective Ch such that the terminal circuit Dc− and the “3×M-2” test circuit from the positive end of the stacked body 10 are closed circuits and the other test circuits are open circuits. Then, the inspection device 100, in the state E, acquires, for example, R_{N+1} based on the formula “R_{N+1}×I_{N+1}=OCV_{N-1}-V_{N-1}”, and acquires R_{N-2} based on the formula “R_{N-2}×I_{N-2}=OCV_{N-4}-V_{N-4}”. Furthermore, the inspection device 100 obtains R_{N+2} based on the formula “R_{N+2}×I_{N+1}=Vp-Vy,” and obtains R_{N-1} based on the formula “R_{N-1}×I_{N-2}=OCV_{N-2}-V_{N-2}”. Note that Vp is the potential of the total positive terminal T+. Vy is positive. In addition, I_{N+1} and I_{N-2} indicate currents flowing through the test circuit DcN and the test circuit DcN-3, respectively.

When the second resistance measurement is completed, the inspection device 100 updates OCV_{N} from OCV1, and then performs the third resistance measurement in the F− state. Specifically, the control device 150 controls the switches 42 of the respective Ch so that the “3×M-1” th test circuit from the positive-side end of the stacked body 10 becomes a closed circuit and the other test circuits and the respective terminal circuits become an open circuit. Then, the inspection device 100 acquires R_{N+1} based on the expression “R_{N+1}×I_{N}=OCV_{N}-V_{N}” and obtains R_{N} based on the expression “R_{N}×I_{N}=OCV_{N-2}-V_{N-2}” in the state F. Then, R_{N-2} is obtained based on the expression “R_{N-2}×I_{N-3}=OCV_{N-3}-V_{N-3}”, and R_{N-3} is obtained based on the expression “R_{N-3}×I_{N-3}=OCV_{N-5}-V_{N-5}”. In addition, I_{N} and I_{N-3} indicate currents flowing through the test circuit DcN-1 and the test circuit DcN-4, respectively.

According to the method of the modification, it is also possible to measure the electrical resistance of the wire connected to the power storage cell in the power storage device with high accuracy. Further, by acquiring two measurement values for the same resistance value, it is possible to improve the reliability of the measurement. However, it is not essential to perform multiple resistance measurements on the same wire. For example, the third resistance measurement can be omitted. The resistance values (R₂) of the respective common-wire parts can be obtained by only measuring the first and second resistances (R_{N+2}).

The embodiment disclosed this time should be considered to be illustrative in all respects and not restrictive. It is intended that the scope of the disclosure be defined by the appended claims rather than the description of the embodiments described above, and that all changes within the meaning and range of equivalency of the claims be embraced therein.

What is claimed is:

1. A method of manufacturing a power storage device including a plurality of power storage cells, the method comprising:
forming wires of the power storage device such that power storage cells adjacent to each other in the power storage device are connected to a common wire; and
measuring an electrical resistance of at least a part of the formed wires, wherein the measuring of the electrical resistance includes measuring, for a common wire portion between a first power storage cell and a second power storage cell adjacent to each other in the power storage device, a voltage of an open circuit including the second power storage cell and the common wire portion while supplying a current to a closed circuit including the first power storage cell and the common wire portion, and acquiring an electrical resistance of the common wire portion using the measured voltage.

2. The method of manufacturing a power storage device according to claim 1, wherein:
the power storage device further includes, in addition to the first power storage cell and the second power storage cell, a third power storage cell located next to the second power storage cell and a fourth power storage cell located next to the third power storage cell; and
the measuring of the electrical resistance includes measuring, for a common wire portion between the third power storage cell and the fourth power storage cell, a voltage of an open circuit including the third power storage cell and the common wire portion while supplying a current to a closed circuit including the fourth power storage cell and the common wire portion, and acquiring an electrical resistance of the common wire portion using the measured voltage.

3. The method of manufacturing a power storage device according to claim 2, wherein:
the forming of the wires includes forming a wire of a terminal circuit not including power storage cells next to the first power storage cell on a side opposite to the second power storage cell;
the terminal circuit is located at an end on a positive electrode side of the entire power storage device or an end of a negative electrode side of the entire power storage device; and
the measuring of the electrical resistance includes measuring, for a common portion between the terminal circuit and a wire of the first power storage cell, a voltage of an open circuit including the first power storage cell and the common portion while supplying a current to the terminal circuit closed, and acquiring an electrical resistance of the common portion using the measured voltage.

4. The method of manufacturing a power storage device according to claim 3, wherein:
the power storage device further includes a fifth power storage cell located next to the fourth power storage cell and a sixth power storage cell located next to the fifth power storage cell;
the measuring of the electrical resistance includes cell voltage measurement, first resistance measurement, and second resistance measurement;
the cell voltage measurement includes measuring an open voltage of each of the first power storage cell, the second power storage cell, the third power storage cell, the fourth power storage cell, the fifth power storage cell, and the sixth power storage cell in the power storage device in a non-energized state;
the first resistance measurement includes
measuring, in a state in which a predetermined current is supplied to a first common wire portion as the common portion between the terminal circuit and the wire of the first power storage cell, a voltage of an open circuit including the first power storage cell and the first common wire portion, and calculating an electrical resistance of the first common wire portion using the measured voltage and the open voltage of the first power storage cell,
measuring, in a state in which a predetermined current is supplied to a third common wire portion as a common wire portion between the second power storage cell and the third power storage cell, a voltage of an open circuit including the second power storage cell and the third common wire portion, and calculating an electrical resistance of the third common wire portion using the measured voltage and the open voltage of the second power storage cell,
measuring, in a state in which a predetermined current is supplied to a fourth common wire portion as a common wire portion between the third power storage cell and the fourth power storage cell, a voltage of an open circuit including the fourth power storage cell and the fourth common wire portion, and calculating an electrical resistance of the fourth common wire portion using the measured voltage and the open voltage of the fourth power storage cell, and
measuring, in a state in which a predetermined current is supplied to a sixth common wire portion as a common wire portion between the fifth power storage cell and the sixth power storage cell, a voltage of an open circuit including the fifth power storage cell and the sixth common wire portion, and calculating an electrical resistance of the sixth common wire portion using the measured voltage and the open voltage of the fifth power storage cell; and
the second resistance measurement includes
measuring, in a state in which a predetermined current is supplied to a second common wire portion as a common wire portion between the first power storage cell and the second power storage cell, a voltage of an open circuit including the second power storage cell and the second common wire portion, and calculating an electrical resistance of the second common wire portion using the measured voltage and the open voltage of the second power storage cell, and
measuring, in a state in which a predetermined current is supplied to a fifth common wire portion as a common wire portion between the fourth power storage cell and the fifth power storage cell, a voltage of an open circuit including the fifth power storage cell and the fifth common wire portion, and calculating an electrical resistance of the fifth common wire portion using the measured voltage and the open voltage of the fifth power storage cell.

5. The method of manufacturing a power storage device according to claim 1, wherein:
the power storage device is a bipolar secondary battery; and
the power storage cells are electrically connected in series in the bipolar secondary battery.
